(19) United States
(12) Patent Application Publication
(10) Pub. No.: US 2019/0373746 A1
(43) Pub. Date: Dec. 5, 2019

(54) CONNECTION MEDIUM DEVICE AND SERVER USING THE SAME

(71) Applicant: GIGA-BYTE TECHNOLOGY CO., LTD., New Taipei City (TW)

(72) Inventors: Chun-Liang Wu, New Taipei City (TW); Ching-Chuan Huang, New Taipei City (TW); Chao-Hsiang Huang, New Taipei City (TW)

(21) Appl. No.: 16/245,264

(22) Filed: Jan. 11, 2019

(30) Foreign Application Priority Data
Jun. 1, 2018 (TW) 107119078

(51) Int. Cl. H05K 5/00; H05K 7/20; H05K 5/02; H05K 5/03

(52) U.S. Cl. CPC H05K 5/0069; H05K 5/03; H05K 5/0286; H05K 7/20172

(57) ABSTRACT

A connection medium device includes a circuit board assembly, a first electric connector, and a second electric connector. The first electric connector is mounted on one side of the circuit board assembly, and is configured to connect to a computation module. The second electric connector is mounted on the other side of the circuit board assembly, and is electrically connected to the first electric connector through the circuit board assembly, and the second electric connector is configured to connect to a storage module. Regarding the server, the computation module and the storage module can be designed and produced modularly in advance through the connection medium device, and after design, the computation module and the storage module are connected through the connection medium device, thereby preparing stocks in advance, performing modular production, reducing working hours, and making the design more flexible.

### CROSS-REFERENCE TO RELATED APPLICATION

This non-provisional application claims priority under 35 U.S.C. § 119(a) to Patent Application No. 107119078 filed in Taiwan, R.O.C. on Jun. 1, 2018, the entire contents of which are hereby incorporated by reference.

### FIELD OF THE INVENTION

The present invention relates to the field of servers, and more particularly, to a connection medium device and a server using the same.

### BACKGROUND

Along with increased demand for various kinds of information, at present, a storage medium and computation are usually constructed by means of a server platform. As far as the applicant knows, a server platform on the market has a storage module and a computation module designed according to demand of a user end, and the storage module and the computation module are mounted in a case, and are connected to each other through, for example, wires and busbars.

However, since the specifications and sizes of various devices are different, the mechanism design in the case needs to be adjusted each time according to demand of a user end, so as to adapt to specifications of different main board assemblies or storage devices.

### SUMMARY OF THE INVENTION

The present invention provides a connection medium device including a circuit board assembly, a first electric connector, and a second electric connector. The first electric connector is mounted on one side of the circuit board assembly and is configured to connect to a computation module. The second electric connector is mounted on the other side of the circuit board assembly, and is electrically connected to the first electric connector through the circuit board assembly, and the second electric connector is configured to connect to a storage module.

In some embodiments, the circuit board assembly includes a first circuit board and a second circuit board, the connection medium device further includes a first signal series connector and a second signal series connector, the first electric connector and the first signal series connector are disposed at different positions on the first circuit board respectively and are electrically connected through the first circuit board, and the second electric connector and the second signal series connector are disposed at different positions on the second circuit board respectively and are electrically connected through the second circuit board, and the first signal series connector and the second signal series connector are plugged, so that the first circuit board and the second circuit board are electrically connected.

Furthermore, in some embodiments, the first circuit board and the second circuit board are disposed orthogonally. Furthermore, in some embodiments, the first signal series connector and the first electric connector are respectively disposed on a first surface and a second surface of the first circuit board. The first surface is opposite to the second surface, the first surface faces the second circuit board, and the second surface faces away from the second circuit board.

In some embodiments, the connection medium device further includes a power supply connector, and the power supply connector is disposed on the first circuit board, and is configured to connect to a power supply.

In some embodiments, the connection medium device further includes a network card connector, and the network card connector is disposed on the first circuit board and is configured to connect to a network card.

In some embodiments, the connection medium device further includes a fan electric connector, and the fan electric connector is disposed on the second circuit board and is configured to connect to a fan.

The present invention also provides a server. The server includes a computation module, a connection medium device, and a storage module. The computation module includes a first case and a main board assembly, the first case includes a first area and a second area, the second area is located on one side of the first area, and the main board assembly is accommodated in the first area and has a main board electric connector. The connection medium device includes a circuit board assembly, a first electric connector, and a second electric connector. The circuit board assembly is mounted in the second area of the first case. The first electric connector is mounted on one side of the circuit board assembly, and is connected to the main board electric connector. The second electric connector is mounted on the other side of the circuit board assembly, and the second electric connector is electrically connected to the first electric connector through the circuit board assembly. The storage module includes a second case, a storage device, and a busbar connector, the second case is assembled with the first case, the storage device is accommodated in the second case, and the busbar connector is electrically connected to the storage device, and is connected to the second electric connector.

In some embodiments, the circuit board assembly includes a first circuit board and a second circuit board, the connection medium device further includes a first signal series connector and a second signal series connector, the first circuit board is disposed on the first case and in contact with two side walls of the first case to separate the first area from the second area, the second circuit board is disposed on a bottom plate of the first case in the second area, the first electric connector and the first signal series connector are respectively disposed on the two opposite surfaces of the first circuit board, and are electrically connected through the first circuit board, the second electric connector and the second signal series connector are disposed at different positions on the second circuit board, and are electrically connected through the second circuit board, and the first signal series connector and the second signal series connector are plugged, so that the first circuit board and the second circuit board are electrically connected.

In some embodiments, the server further includes a fan assembly, the connection medium device further includes a fan electric connector, the fan assembly includes a fan base and a fan, the fan is accommodated in the fan base, and the fan is assembled with the fan electric connector. The fan base and two side walls of the first case in the second area respectively have a connection hole and a protruding column that are corresponding to each other, the protruding column is inserted into the connection hole, so that the fan assembly is assembled with the first case.

In some embodiments, an upper cover is connected to the first case and in contact with the two side walls to seal the second area and shield the fan assembly and the connection medium device.

In some embodiments, the computation module further includes a plurality of positioning assemblies and a drawing assembly, the positioning assemblies are mounted on two side walls of the first case in the first area, the positioning assemblies are in contact with the drawing assembly, the main board assembly is mounted on the drawing assembly, and the drawing assembly is pushed into the first case towards the second area, so that the first electric connector and the main board electric connector are connected.

In some embodiments, the server further includes a power supply and a power supply connector, the power supply is accommodated in the first area of the first case, and the power supply connector is disposed on the circuit board assembly, and is connected to the power supply.

The connection medium device can be used to design the server modularly through assembly, the storage module and the computation module can be designed and assembled in advance, and after design and assembly, the storage module and the computation module are electrically connected through the connection medium device and then can be used, thereby realizing modular and flexible production during the whole design, and preparing stocks in advance to reduce working hours. Furthermore, regarding the whole design, the storage module and the computation module are serially connected through a circuit board, thereby reducing use of wires significantly, increasing the internal space of the server, providing a wider air duct, and improving heat dissipation effects.

### BRIEF DESCRIPTION OF THE DRAWINGS

The exemplary embodiments of the present invention are further described in detail with reference to the accompanying drawings, and then, the advantages and the features of the aforementioned and other exemplary embodiments of the present invention will become clearer, wherein:

FIG. 1 is a schematic exploded front view of an embodiment of a connection medium device;

FIG. 2 is a schematic exploded rear view of an embodiment of a connection medium device;

FIG. 3 is a schematic exploded front view of a server using a connection medium device;

FIG. 4 is a schematic three-dimensional rear view of a storage module of a server;

FIG. 5 is a schematic three-dimensional rear view of a first case of a server;

FIG. 6 is a schematic three-dimensional view of a server using a connection medium device;

FIG. 7 is a schematic diagram of a changed state of a storage module of a server; and

FIG. 8 to FIG. 10 are partial three-dimensional rear views of different embodiments of a computation module of a server.

### DETAILED DESCRIPTION OF THE INVENTION

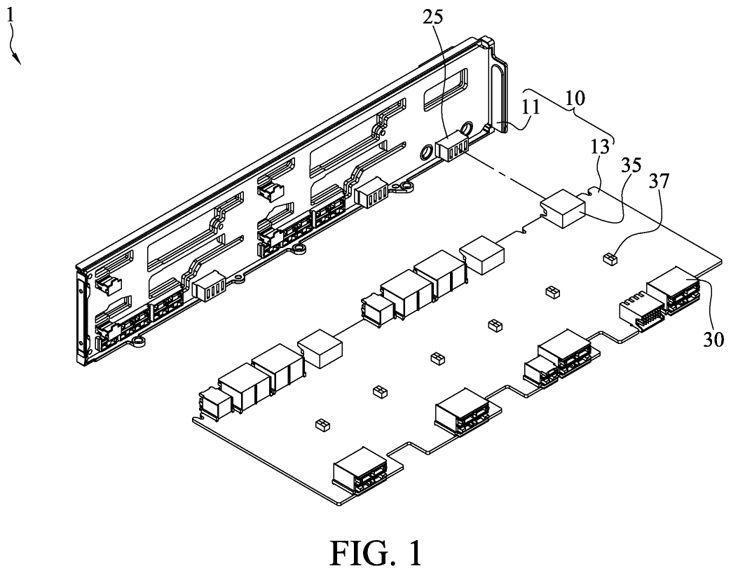

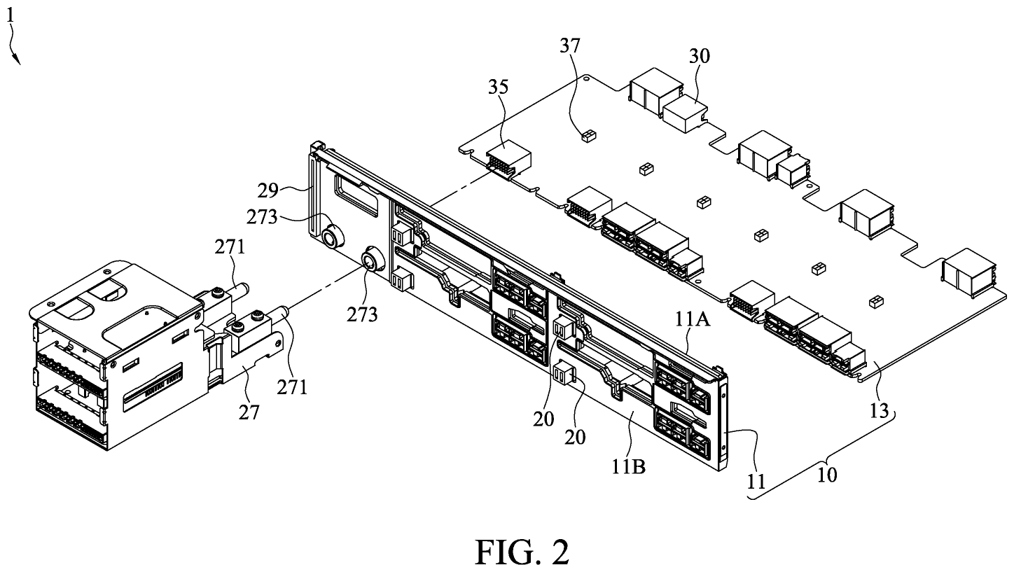

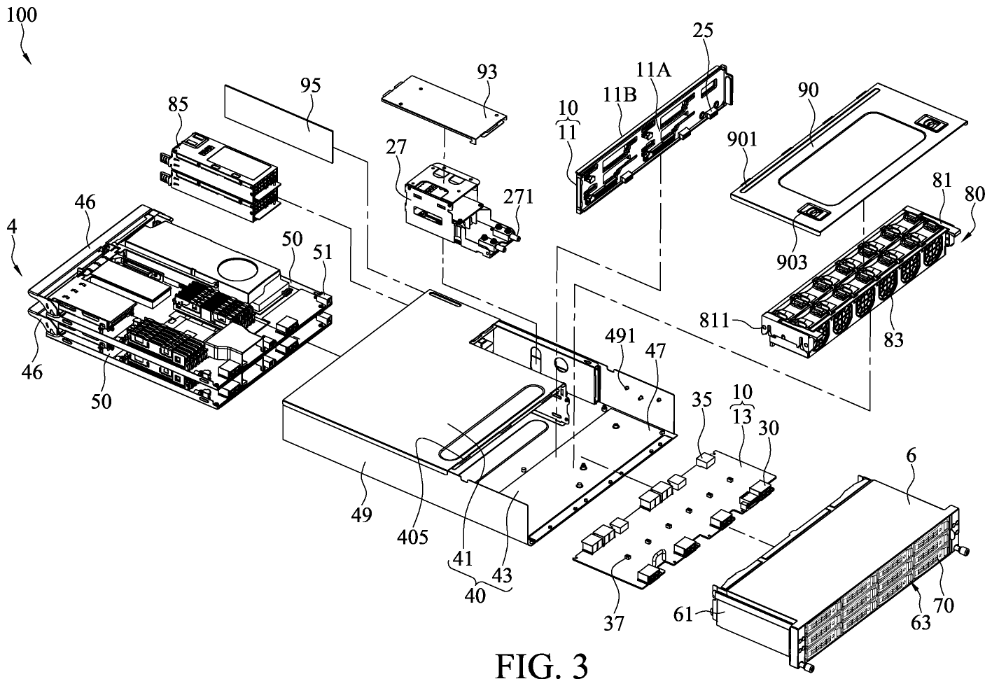

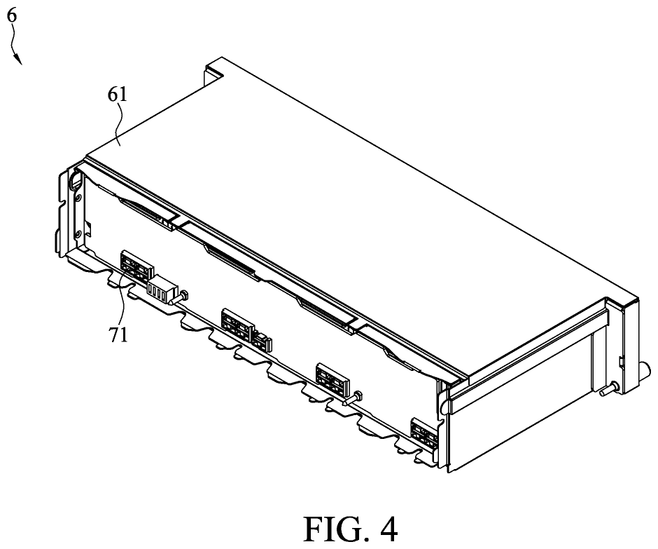

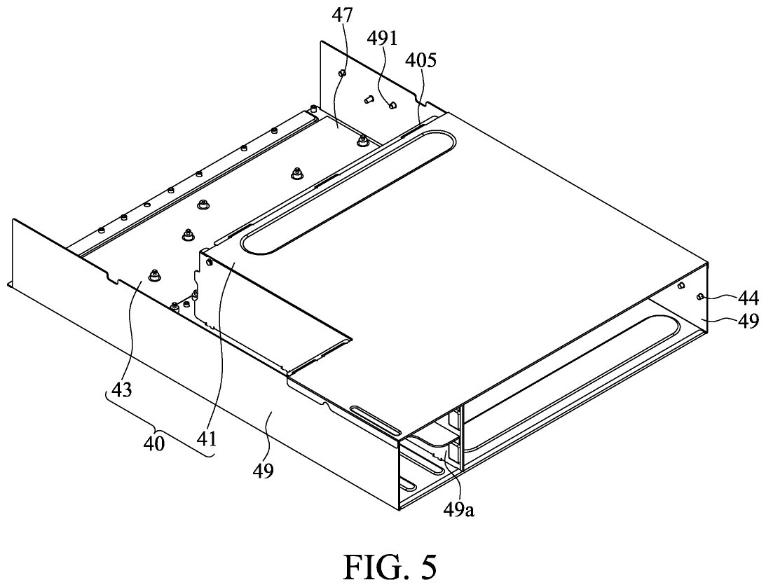

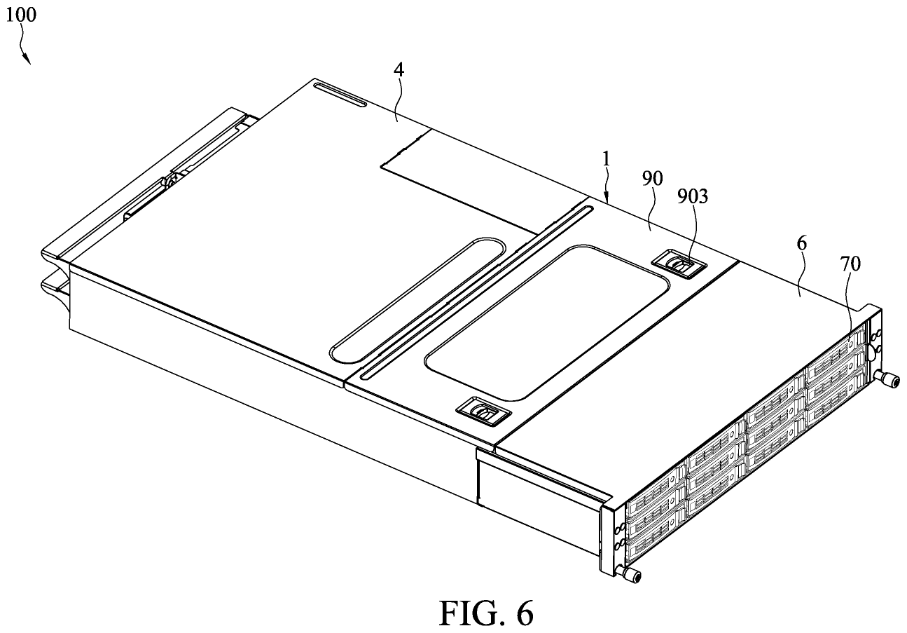

FIG. 1 is a schematic exploded front view of an embodiment of a connection medium device. FIG. 2 is a schematic exploded rear view of an embodiment of a connection medium device. FIG. 3 is a schematic exploded front view of a server using a connection medium device. FIG. 4 is a schematic three-dimensional rear view of a storage module of a server. FIG. 5 is a schematic three-dimensional rear view of a first case of a server. FIG. 6 is a schematic three-dimensional view of a server using a connection medium device. The present application provides a connection medium device 1 and a server 100 using the connection medium device 1. Herein, the connection medium device 1 can assist the server 100 to be designed and assembled modularly.

As shown in FIG. 1, FIG. 2 and FIG. 3, the connection medium device 1 includes a circuit board assembly 10, first electric connectors 20, and second electric connectors 30. The first electric connectors 20 are mounted on one side of the circuit board assembly 10, and are configured to connect to a computation module 4. The second electric connectors 30 are mounted on the other side of the circuit board assembly 10, the second electric connectors 30 are electrically connected to the first electric connectors 20 through the circuit board assembly 10, and the second electric connectors 30 are configured to connect to a storage module 6. Herein, the first electric connectors 20 and the second electric connectors 30 may have 100 to 300 pins, for example, 220 pins, thereby achieving centralization of electrical connections.

As shown in FIG. 1 and FIG. 2, in this embodiment, the circuit board assembly 10 includes a first circuit board 11 and a second circuit board 13. The connection medium device 1 further includes first signal series connectors 25 and second signal series connectors 35, the first electric connectors 20 and the first signal series connectors 25 are disposed at different positions on the first circuit board 11 respectively, and are electrically connected through the first circuit board 11. The second electric connectors 30 and the second signal series connectors 35 are disposed at different positions on the second circuit board 13, and are electrically connected through the second circuit board 13. The first signal series connectors 25 and the second signal series connectors 35 are plugged, so that the first circuit board 11 and the second circuit board 13 are electrically connected. In this embodiment, the first circuit board 11 and the second circuit board 13 are combined and are serially connected through the first signal series connectors 25 and the second signal series connectors 35, so as to form the circuit board assembly 10, but this is only an example and the present invention is not limited thereto. For example, when a server 100 with a narrow internal space is designed, a single circuit board assembly may alternatively be used. Alternatively, if the internal space of the server 100 is relatively irregular, more circuit boards and electric connectors may be combined.

As shown in FIG. 1 and FIG. 2, in this embodiment, the first circuit board 11 and the second circuit board 13 are disposed orthogonally, and are assembled through the first signal series connectors 25 and the second signal series connectors 35, but this is only an example and the present invention is not limited thereto. For example, if the server 100 is a flat-type server, the first circuit board 11 and the second circuit board 13 may alternatively be serially connected horizontally.

As shown in FIG. 1 and FIG. 2, in this embodiment, the first signal series connectors 25 and the first electric connectors 20 are disposed on a first surface 11A and a second surface 11B of the first circuit board 11 respectively. The first surface 11A is opposite to the second surface 11B. More specifically, the first surface 11A faces the second circuit board 13, and the second surface 11B faces away from the second circuit board 13. In this embodiment, the first circuit board 11 is a circuit substrate with multiple layers of wires, and the front and rear sides thereof may be assembled with the computation module 4 and the second circuit board 13 respectively. However, the assembly manner is only an example, and the present invention is not limited thereto. For example, if the first circuit board 11 is mounted in a platy form, it is unnecessary to dispose electric connectors on the front and rear sides thereof. Herein, multiple first signal series connectors 25 and multiple second signal series connectors 35 are provided, but this is only an example and the present invention is not limited thereto, as long as electric connection and signal transfer functions can be achieved. In some embodiments, a single first signal series connector 25 and a single second signal series connector 35 are also allowed.

As shown in FIG. 2 and FIG. 3, in some embodiments, the connection medium device 1 further includes a power supply connector 27. The power supply connector 27 is disposed on the first circuit board 11, and is configured to connect to a power supply 85. In this embodiment, the power supply connector 27 and the first electric connectors 20 are disposed on the second surface 11B together, so as to be serially connected to a power supply from the computation module 4, and supply power for the second circuit board 13 and the storage module 6. Herein, a power supply plug 271 of the power supply connector 27 is assembled with a power supply socket 273 of the first circuit board 11, so that the power supply connector 27 and the first circuit board 11 are electrically connected, but this is only an example and the present invention is not limited thereto.

As shown in FIG. 2 and FIG. 3, in some embodiments, the connection medium device 1 further includes a network card connector 29. The network card connector 29 is disposed on the first circuit board 11 and is configured to connect to a network card 95. In this embodiment, the power supply connector 27 and the first electric connectors 20 are disposed on the second surface 11B together. The independent network card 95 is directly used to achieve a networking function. This is only an example, and the network card 95 is not limited to being directly mounted on the first circuit board 11. For example, the network card may be built in a main board assembly 50 of the computation module 4 or mounted on the main board assembly 50.

Referring to FIG. 1 and FIG. 3 again, in some embodiments, the connection medium device 1 further includes fan electric connectors 37 that are disposed on the second circuit board 13 to be connected to fans. Herein, in the figures, multiple fan electric connectors 37 are provided and may be corresponding to multiple fans 83, but this is only an example and the present invention is not limited thereto, and in fact, the quantities of the fans 83 and the fan electric connectors 37 may be adjusted according to actual demand.

As shown in FIG. 3 to FIG. 6, the server 100 includes the connection medium device 1, the computation module 4, and the storage module 6. The computation module 4 includes a first case 40 and main board assemblies 50. The first case 40 includes a first area 41 and a second area 43, and the second area 43 is located at one end of the first area 41. Herein, the second area 43 is located at the front end of the first area 41, and they are in communication with each other. The main board assemblies 50 are accommodated in the first area 41, and the main board assemblies 50 have main board electric connectors 51. The connection medium device 1 includes the circuit board assembly 10, the first electric connectors 20, and the second electric connectors 30, and the circuit board assembly 10 is mounted in the second area 43 of the first case 40. The first electric connectors 20 are mounted on one side of the circuit board assembly 10, and are connected to the main board electric connectors 51. The second electric connectors 30 are mounted on the other side of the circuit board assembly 10, and the second electric connectors 30 are electrically connected to the first electric connectors 20 through the circuit board assembly 10. The storage module 6 includes a second case 60, storage devices 70, and busbar connectors 71. The second case 60 is assembled with the first case 40, the storage devices 70 are accommodated in the second case 60, and the busbar connectors 71 are electrically connected to the storage devices 70 and are connected to the second electric connectors 30, so as to be electrically connected to the computation module 4 and the storage module 6 through the connection medium device 1, thereby achieving the form in FIG. 6. Therefore, the computation module 4 and the storage module 6 can be designed and configured separately in advance, and then modularly assembled by using the connection medium device 1.

As shown in FIG. 3 to FIG. 6, in this embodiment, the circuit board assembly 10 includes the first circuit board 11 and the second circuit board 13, and the connection medium device 1 further includes the first signal series connectors 25 and the second signal series connectors 35. The first circuit board 11 is disposed on the first case 40 and is in contact with two side walls 49 thereof, so as to further separate the first area 41 from the second area 43, and the second circuit board 13 is disposed on a bottom plate 47 of the first case 41 in the second area 43. The first electric connectors 20 and the first signal series connectors 25 are separately disposed on the two opposite surfaces 11A and 11B of the first circuit board 11, and are electrically connected through the first circuit board 11. The second electric connectors 30 and the second signal series connectors 35 are disposed at different positions on the second circuit board 13, and are electrically connected through the second circuit board 13. The first signal series connectors 25 and the second signal series connectors 35 are plugged, so that the first circuit board 11 and the second circuit board 13 are electrically connected. Herein, in the embodiments shown in FIG. 3 and FIG. 4, multiple first electric connectors 20, first signal series connectors 25, second electric connectors 30, second signal series connectors, main board assemblies 50, and storage devices 70 are provided, but in fact, the quantities of various electric connectors, main board assemblies 50, and storage devices 70 may be adjusted according to use demand, and the quantities of the first electric connectors 20, the second electric connectors 30, the main board electric connectors 51, and the busbar connectors 71 do not need to be identical.

Referring to FIG. 3 again, the server 100 further includes a fan assembly 80, and the connection medium device 1 further includes fan electric connectors 37. The fan assembly 80 includes a fan base 81 and fans 83, and the fans 83 are accommodated in the fan base 81 and are assembled with the fan electric connectors 37. Herein, in this embodiment, the fan assembly 80 is located above the second circuit board 13 as a whole. The fan electric connectors 37 are located between the second electric connectors 30 and the second signal series connectors 35. After the fans 83 and the fan electric connectors 37 are assembled, they can dissipate heat of the server 100. In addition, the fan base 81 and the two side walls 49 of the first case 40 in the second area 43 respectively have connection holes 811 and protruding columns 491 that are corresponding to each other, and the protruding columns 491 are inserted into the connection holes 811, so that the fan assembly 83 is assembled with the first case 40.

Herein, FIG. 3 shows multiple fan electric connectors 37 and fans 83, but this is only an example. Regarding modular design, the quantity of the fan electric connectors 37 may be one or more, and the quantity of the fans 83 may be adjusted according to the specification of a design, and does not need to be the same as the quantity of the fan electric connectors 37, and the whole quantity configuration is not limited thereto. Additionally, the connection holes 811 on the fan base 81 may alternatively be exchanged with the protruding columns 491 on the first case 40, and furthermore, fasteners 813 may also be provided, so that after the protruding columns 491 are inserted into the connection holes 811, the protruding columns 491 can be fastened so as not to get loose.

Referring to FIG. 3 again, the server 100 further includes an upper cover 90, and the upper cover 90 is connected to the first case 40 and in contact with the two side walls 49, so as to shield the second area 43, as well as the fan assembly 80 and the connection medium device 1, and the assembled server 100 is shown in FIG. 6. Furthermore, the upper cover 90 may have a bump 901 clamped in a through hole 405 at the edge of the first case 40, so that the upper cover 90 is fixed on the first case 40. Furthermore, the upper cover 90 may be further provided with slider fasteners 903 thereon. The slider fasteners 903 enable the upper cover 90 to be lifted easily, so that the upper cover 90 can be assembled with or separated from the first case selectively. Therefore, the upper cover 90 can be opened or closed more easily.

As shown in FIG. 3 and FIG. 5, the computation module 4 further includes a positioning assembly 44 and a drawing assembly 46, and the positioning assembly 44 is mounted on the two side walls 49 of the first case 40 in the first area 41. Herein, the bottom plate 47 and the two side walls 49 of the first case 40 extend continuously in the first area 41 and the second area 43 and the positioning assembly 44 may be protruding columns. The drawing assembly 46 abuts against the positioning assembly 44, the main board assemblies 50 are mounted on the drawing assembly 46, when the drawing assembly 46 is pushed into the first case 40 towards the second area 43, the drawing assembly 46 may be positioned on the positioning assembly 44, and when the drawing assembly 46 is pushed to approach the second area 43, the first electric connectors 20 and the main board electric connectors 51 are connected to be fixed. This is only an example and the present invention is not limited thereto, and the positioning assembly 44 may alternatively be a sliding rail or a sliding slot that can be assembled with the drawing assembly 46.

Additionally, referring to FIG. 3 and FIG. 4 again, the storage module 6 further includes engagement slots 63 that are disposed in the second case 60 to accommodate the storage devices 70. Herein, the storage device 70 may be a 2.5-inch hard disk, a 3.5-inch hard disk, or a storage element in another form. Each storage device 70 may be connected to one busbar connector 71 or multiple storage devices 70 may be connected to the busbar connectors 71. When the storage module 6 is connected to the connection medium device 1, the second electric connectors 30 are connected to the busbar connectors 71. A circuit board and an electric connector may be further disposed at a position on the rear side of the storage module 6 that is to be connected to the connection medium device 1, the electric connector is disposed on one side of the circuit board to connect all the storage devices 70, and the busbar connectors 71 are disposed on the other side to be connected to the second electric connectors 30. However, this is only an example, and the present invention is not limited thereto.

Referring to FIG. 3 again, the server 100 further includes the power supply 85 and the power supply connector 27, the power supply 85 and the power supply connector 27 are accommodated in the first area 41 of the first case 40, the power supply connector 27 may be disposed on the first circuit board 11 through assembly, and then connected to the power supply 27. However, this is only an example, and the present invention is not limited thereto. For example, in some embodiments, the power supply connector 27 may alternatively be mounted on the main board assemblies 50, so that the main board assembly 50 can be supplied with power by different power supplies 27. Furthermore, the server 100 further includes a side upper cover 93 that is assembled with the first case 40, so as to shield the power supply 85 and the power supply connector 27.

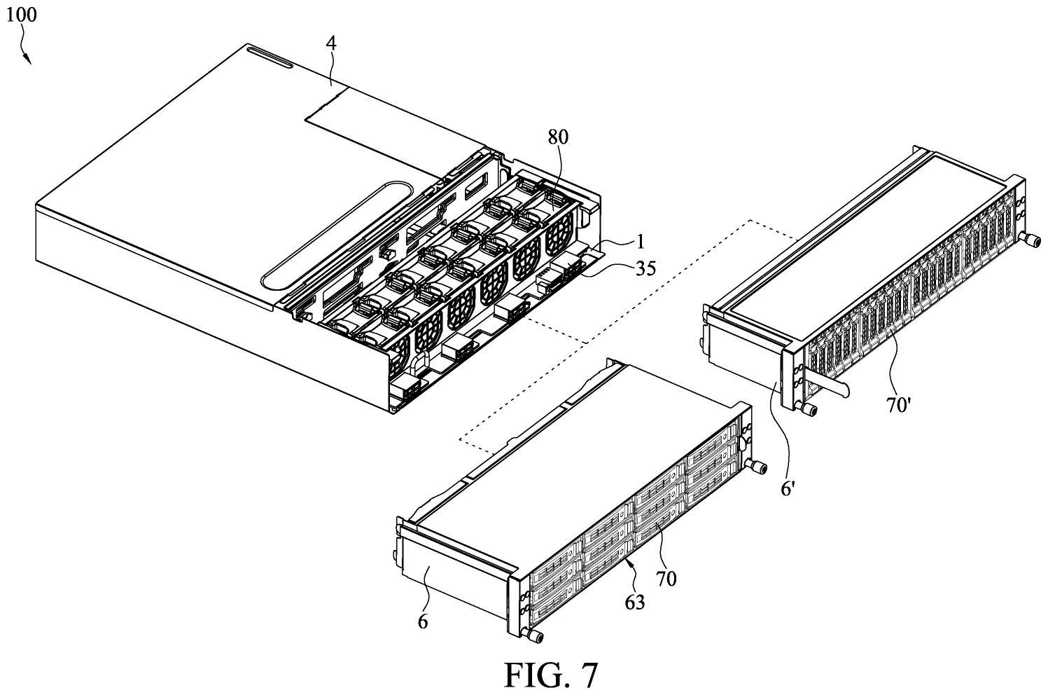

FIG. 7 is a schematic diagram of a changed state of the storage module of the server. Herein, the storage module 6 further includes multiple storage devices 70 that are 3.5-inch hard disks. Herein, the storage module 6 may alternatively be replaced with a storage module 6′ according to a design. A storage device 70′ of the storage module 6′ is a 2.5-inch hard disk. It can be understood that, the storage module 6 may be designed and assembled separately, and after being assembled, the storage module 6 is connected to the computation module 4 through the connection medium device 1. This is only an example, and the present invention is not limited thereto.

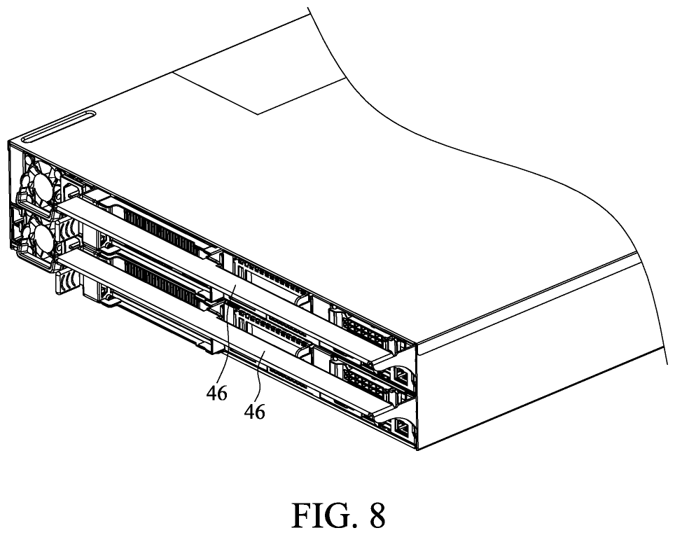

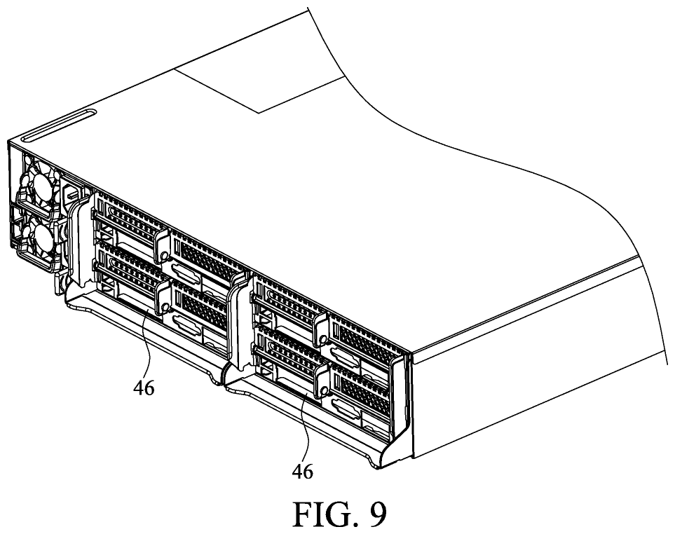

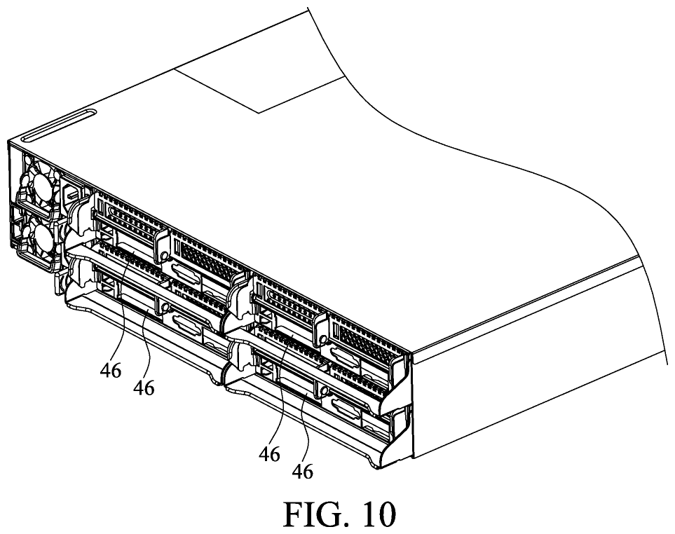

FIG. 8 to FIG. 10 are partial three-dimensional rear views of different embodiments of the computation module of the server. As shown in FIG. 7 to FIG. 9 and FIG. 3, each drawing assembly 46 is mounted with a main board assembly 50 thereon, and it can be understood that, as shown in FIG. 8, the main board assembles 50 may be configured at the upper side and the lower side respectively. Alternatively, as shown in FIG. 9, the main board assembles 50 may be configured at the upper side, the lower side, the left side, and the right side respectively. Alternatively, as shown in FIG. 10, the main board assembles 50 may be configured at the left side and the right side respectively. This is only an example, and the present invention is not limited thereto. It can be understood that, as shown in FIG. 7 to FIG. 10, the quantities and configuration manners of the computation modules 4 and storage modules 6 may be adjusted appropriately according to actual demand and the element specification, and furthermore, according to the existing size and specification, the computation module 4 and the storage module 6 may be designed in advance to achieve semi-finished products that are assembled to achieve the server 100. Therefore, the flexibility is higher, and the computation module 4 and the storage module 6 can be pre-made due to the modular and standard design, thereby reducing working hours.

In view of the above, the connection medium device 1 can be used to design the server 100 modularly through assembly, the storage module 6 and the computation module 4 can be designed and assembled in advance according to a required specification and quantity, and after design and assembly, the storage module 6 and the computation module 4 are electrically connected through the connection medium device 1 and then can be used, thereby realizing modular and more flexible production during the whole design, preparing stocks in advance to reduce working hours. Furthermore, regarding the whole design of the server 100, the storage module 6 and the computation module 4 are serially connected through a circuit board, thereby reducing use of wires significantly, increasing the internal space of the server, providing a wider air duct, and improving heat dissipation effects.

Although the present invention is described with reference to exemplary embodiments that are considered to be practical at present, it should be understood that, the present invention is not limited to the disclosed embodiments, and on the contrary, is intended to be applicable to various modifications and equivalent configurations included in the spirit and the scope of the appended claims.

1. A connection medium device, comprising:
a circuit board assembly comprising a first circuit board and a second circuit board, wherein the first circuit board and the second circuit board are disposed orthogonally;
a first signal series connector disposed on a disposed on a first surface of the first circuit board;
a first electric connector disposed on a second surface of the first circuit board, electrically connected to the first signal series connector connected through the first circuit board, and configured to connect to a computation module, wherein the first surface is opposite to the second surface, the first surface faces the second circuit board and, and the second surface faces away from the second circuit board, and the first signal series connectors and the first electric connectors are protruded from the first surface and the second surface, respectively;
a second electric connector disposed on the second circuit board, and the second electric connector configured to connect to a storage module; and
a second series connector disposed on the second circuit board, and positioned on different positions from the second electric connector, and electrically connected to the second electric connector through the second circuit board, wherein and the first signal series connector and the second signal series connector are plugged into each other, so that the first circuit board and the second circuit board are electrically connected.

2. (canceled)

3. (canceled)

4. (canceled)

5. The connection medium device according to claim 1, further comprising a power supply connector, wherein the power supply connector is disposed on the first circuit board and is configured to connect to a power supply.

6. The connection medium device according to claim 1, further comprising a network card connector, wherein the network card connector is disposed on the first circuit board and is configured to connect to a network card.

7. The connection medium device according to claim 1, further comprising a fan electric connector, wherein the fan electric connector is disposed on the second circuit board and is configured to connect to a fan.

8. A server, comprising:
a computation module, comprising a first case and a main board assembly, wherein the first case comprises a first area and a second area, the second area is located at one end of the first area, the main board assembly is accommodated in the first area and has a main board electric connector;
a connection medium device, comprising:
a circuit board assembly, mounted in the second area of the first case, wherein the circuit board assembly comprises a first circuit board and a second circuit board, and the first circuit board and the second circuit board are disposed orthogonally;
a first signal series connector disposed on a disposed on a first surface of the first circuit board;
a first electric connector disposed on a second surface of the first circuit board, electrically connected to the first signal series connector connected through the first circuit board, and connected to the main board electric connector, wherein the first surface is opposite to the second surface, the first surface faces the second circuit board and, and the second surface faces away from the second circuit board, and the first signal series connectors and the first electric connectors are protruded from the first surface and the second surface, respectively;
a second electric connector disposed on the second circuit board; and
a second series connector disposed on the second circuit board, and positioned on different positions from the second electric connector, and electrically connected to the second electric connector through the second circuit board, wherein and the first signal series connector and the second signal series connector are plugged into each other, so that the first circuit board and the second circuit board are electrically connected; and
a storage module, comprising a second case, a storage device, and a busbar connector, wherein the second case and the first case are assembled, the storage device is accommodated in the second case, and the busbar connector is electrically connected to the storage device and is connected to the second electric connector.

9. The server according to claim 8, wherein the first circuit board is disposed on the first case and abuts against two side walls of the first case to separate the first area and the second area, the second circuit board is disposed on a bottom plate of the first case in the second area.

10. The server according to claim 8, further comprising a fan assembly, wherein the connection medium device further comprises a fan electric connector, the fan assembly comprises a fan base and a fan, the fan is accommodated in the fan base and is assembled with the fan electric connector, the fan base and two side walls of the first case in the second area respectively have a connection hole and a protruding column that are corresponding to each other, and the protruding column is inserted into the connection hole, so that the fan assembly is assembled with the first case.

11. The server according to claim 10, further comprising an upper cover, wherein the upper cover is connected to the first case and in contact with the two side walls to seal the second area and shield the fan assembly and the connection medium device.

12. The server according to claim 8, wherein the computation module further comprises a plurality of positioning assemblies and a drawing assembly, the positioning assemblies are mounted on two walls of the first case in the first area, the positioning assemblies are in contact with the drawing assembly, the main board assembly is mounted on the drawing assembly, and the drawing assembly is pushed into the first case towards the second area, so that the first electric connector and the main board electric connector are connected.

13. The server according to claim 8, further comprising a power supply and a power supply connector, wherein the power supply is accommodated in the first area of the first case, and the power supply connector is disposed on the circuit board assembly and is connected to the power supply.
